(19) United States
(12) Patent Application Publication
(10) Pub. No.: US 2024/0386182 A1
(43) Pub. Date: Nov. 21, 2024

(54) ROUTING METHOD AND SYSTEM IN MULTILAYER STRUCTURE

(71) Applicants: SAMSUNG SDS CO., LTD., Seoul (KR); UNIST (ULSAN NATIONAL INSTITUTE OF SCIENCE AND TECHNOLOGY), Ulsan (KR)

(72) Inventors: Jae Ho YANG, Seoul (KR); Rak-Kyeong Seong, Ulsan (KR); Chang Hyeong Lee, Ulsan (KR); Hee Jin Choi, Ulsan (KR); Min Ji Lee, Ulsan (KR)

(73) Assignees: SAMSUNG SDS CO., LTD., Seoul (KR); UNIST (ULSAN NATIONAL INSTITUTE OF SCIENCE AND TECHNOLOGY), Ulsan (KR)

(21) Appl. No.: 18/667,693

(22) Filed: May 17, 2024

(30) Foreign Application Priority Data
May 19, 2023 (KR) 10-2023-0065106
Oct. 13, 2023 (KR) 10-2023-0136417

(51) Int. Cl. G06F 30/394; G06N 20/00

(52) U.S. Cl. CPC G06F 30/394; G06N 20/00

(57) ABSTRACT

A routing method in a multilayer structure is provided. The routing method may include: acquiring a routing problem, wherein the routing problem is a problem of generating a path set that includes respective paths for multiple node groups arranged in a multilayer structure, generating a routing order example for the multiple node groups, generating a path set for the multiple node groups by executing a routing algorithm based on the routing order example, establishing a training set by obtaining a cost of the generated path set based on a predefined evaluation function, and training a deep learning model to predict a routing order using the training set.

### CROSS-REFERENCE TO RELATED APPLICATION

This application claims priority from Korean Patent Application No. 10-2023-0065106 filed on May 19, 2023, in the Korean Intellectual Property Office, and Korean Patent Application No. 10-2023-0136417 filed on Oct. 13, 2023, in the Korean Intellectual Property Office, and all the benefits accruing therefrom under 35 U.S.C. 119, the contents of which in its entirety are herein incorporated by reference.

### BACKGROUND

### 1. Field

The present disclosure relates to a method of performing routing on a plurality of node groups disposed in a multilayer structure.

### 2. Description of the Related Art

In the field of semiconductors, the process of setting up wiring within semiconductor packages with a multilayer structure and calculating paths for such wirings is referred to as routing. This routing task is usually performed by design professionals using specialized Electronic Design Automation (EDA) tools and is time-consuming. Consequently, there is ongoing research into routing methods that can automate and optimize routing by creating paths for target groups to be connected, known as “nets,” within a multilayer structure.

However, prior studies have not significantly considered the routing order between the target groups (i.e., the sequence in which paths are generated between the target groups). Since the outcomes of routing can vary greatly depending on the routing order, it is crucial to accurately determine this order for achieving the most optimal results.

### SUMMARY

Aspects of the present disclosure provide a routing method and system that can accurately generate an optimal (or near-optimal) path set for multiple node groups in a multilayer structure.

Aspects of the present disclosure also provide a routing method and system that can generate an optimal (or near-optimal) path set for multiple node groups in a multilayer structure at reduced cost.

Aspects of the present disclosure also provide a method and system for accurately determine the routing order for multiple node groups in a multilayer structure.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, there is provided a routing method in a multilayer structure, performed by at least one computing device. The routing method may include: acquiring a routing problem, wherein the routing problem is a problem of generating a path set that includes respective paths for multiple node groups arranged in a multilayer structure, generating a routing order example for the multiple node groups, generating a path set for the multiple node groups by executing a routing algorithm based on the routing order example, establishing a training set by obtaining a cost of the generated path set based on a predefined evaluation function, and training a deep learning model to predict a routing order using the training set.

In some embodiments, the acquired routing problem may include a plurality of routing problems, and the plurality of routing problems may include a first routing problem, a second routing problem generated by modifying the first routing problem, and a third routing problem generated by randomly disposing a plurality of nodes in the multilayer structure.

In some embodiment, the generating the routing order example, may comprise generating the routing order example using a predefined heuristic evaluation function, and the predefined heuristic evaluation function is a function that estimates a cost of a path set generated based on a specific routing order.

In some embodiments, the generating the routing order example, may comprise generating the routing order example by modifying an existing routing order example using a genetic algorithm.

In some embodiments, the generating the path set, may comprise generating a plurality of path sets by executing a plurality of different routing algorithms.

In some embodiments, the routing problem may be defined based on a multilayer grid map, the establishing the training set, may comprises: creating a single-layer grid map by compressing the multilayer grid map, and extracting at least one feature that constitutes an input for the deep learning model from the single-layer grid map.

In some embodiments, at least one feature may include a number of nodes in a specific node group on the single-layer grid map.

In some embodiments, extracting the at least one feature, may comprises: deriving a path that connects nodes belonging to a specific node group on the single-layer grid map, and extracting a feature for the specific node group based on the derived path.

In some embodiments, extracting the feature for the specific node group, may comprise extracting a length of the derived path as the feature for the specific node group.

In some embodiments, extracting the feature for the specific node group, may comprise extracting at least one of a horizontal length, vertical length, and area of a grid region containing the derived path on the single-layer grid map as the feature for the specific node group.

In some embodiments, extracting the feature for the specific node group, may comprise extracting a number of branches present on the derived path as the feature for the specific node group.

In some embodiments, extracting the at least one feature, may comprise: deriving a first path that connects nodes belonging to a first node group among the multiple node groups on the single-layer grid map; deriving a second path that connects nodes belonging to a second node group among the multiple node groups on the single-layer grid map, and extracting a feature for the first or second node group by measuring a length of an overlapping section between the first and second paths.

In some embodiments, the multiple node groups may be multiple first node groups, and the routing method further may comprise: acquiring a target multilayer grid map where multiple second node groups are disposed; extracting a feature for the multiple second node groups from a single-layer grid map obtained by compressing the target multilayer grid map, and predicting a routing order to be applied to the multiple second node groups by inputting information on the multiple second node groups and the feature for the multiple second node groups into the trained deep learning model.

In some embodiments, the establishing the training set, may comprise establishing the training set by adding features of a node cluster that includes at least some of the multiple node groups, the node cluster may refer to a collection of node groups with the same purpose or the same attributes, and the features of the node cluster may include at least one of importance, common attributes, and common design rules.

In some embodiments, the deep learning model may be configured to output values representing routing orders for input node groups, among the generated routing order examples, a routing order example with a cost below a threshold may be set as a correct answer label for the multiple node groups, and the training the deep learning model, may comprise: predicting a routing order for the multiple node groups through the deep learning model, and updating weight parameters of the deep learning model based on a loss between the predicted routing order and the correct answer label.

In some embodiments, the deep learning model may be configured to output a cost of a path set for node groups having a specific routing order, the obtained cost may be set as a correct answer label for the multiple node groups, the training the deep learning model, may comprise: predicting a cost corresponding to a routing order associated with a correct answer label through the deep learning model, and updating weight parameters of the deep learning model based on a loss between the predicted cost and the correct answer label.

In some embodiments, the multiple node groups may be multiple first node groups, and the routing method may further comprise: acquiring a target multilayer grid map where multiple second node groups are disposed; extracting a feature for the multiple second node groups from a single-layer grid map obtained by compressing the target multilayer grid map, and predicting a routing order to be applied to the multiple second node groups by inputting information on the multiple second node groups and the feature for the multiple second node groups into the trained deep learning model.

According to another aspect of the present disclosure, there is a provided routing system. The routing system may include: at least one processor, and a memory configured to store a computer program executable by the at least one processor, wherein the computer program may include instructions for operations of: acquiring a routing problem, wherein the routing problem is a problem of generating a path set that includes respective paths for multiple node groups arranged in a multilayer structure, generating a routing order example for the multiple node groups, generating a path set for the multiple node groups by executing a routing algorithm based on the routing order example, establishing a training set by obtaining a cost of the generated path set based on a predefined evaluation function, and training a deep learning model to predict a routing order using the training set.

According to another aspect of the present disclosure, there is a provided a non-transitory computer-readable medium storing a computer program that is executable by at least one processor to execute: acquiring a routing problem, wherein the routing problem is a problem of generating a path set that may include respective paths for multiple node groups arranged in a multilayer structure, generating a routing order example for the multiple node groups, generating a path set for the multiple node groups by executing a routing algorithm based on the routing order example, establishing a training set by obtaining a cost of the generated path set based on a predefined evaluation function, and training a deep learning model to predict a routing order using the training set.

According to the aforementioned and other embodiments of the present disclosure, a path set for multiple node groups can be generated by predicting a routing order for the multiple node groups and executing a routing algorithm based on the predicted routing order, through a deep learning model. In this case, the computational cost of creating a path set can be significantly reduced (as there is no need to repeatedly execute the routing algorithm by changing routing orders), and a suitable (i.e., optimal or near-optimal) path set can be accurately generated for the multiple node groups.

Furthermore, utilizing heuristic or meta-heuristic algorithms can create high-quality routing order examples with low computational costs, thus improving the performance (i.e., prediction accuracy) of the deep learning model that predicts routing orders.

Additionally, by modifying existing routing problems or randomly arranging nodes, diverse routing problems can be generated, enriching the training set and further enhancing the performance of the deep learning model.

Also, using routing order examples with routing costs below a threshold as correct answer labels can also boost the performance of the deep learning model.

Lastly, employing various 2D features associated with 3D routing results as inputs for the deep learning model can lower the task difficulty of the deep learning model and enhance the precision accuracy of the deep learning model.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is an exemplary diagram for explaining the operation of a routing system according to some embodiments of the present disclosure;

FIG. 2 is an exemplary diagram illustrating a routing problem in a multilayer structure, which can be referenced in some embodiments of the present disclosure;

FIG. 3 is an exemplary diagram illustrating the concept of a routing order and how routing results can vary depending on the routing order, which can be referenced in some embodiments of the present disclosure;

FIG. 4 is an exemplary diagram for further explaining the operation of the routing system according to some embodiments of the present disclosure;

FIG. 5 is an exemplary flowchart illustrating a routing method in a multilayer structure according to some embodiments of the present disclosure;

FIG. 6 is an exemplary flowchart illustrating how to establish a training set, as performed in the routing method of FIG. 5;

FIG. 7 is an exemplary diagram for explaining how to generate routing order examples according to some embodiments of the present disclosure;

FIG. 8 is an exemplary diagram illustrating how to generate path sets from routing order examples and evaluate the costs of the path sets according to some embodiments of the present disclosure;

FIG. 9 is an exemplary diagram for explaining how to create a single-layer grid map according to some embodiments of the present disclosure;

FIG. 10 is an exemplary diagram for explaining a 2D feature associated with the number of nodes and how to extract such 2D feature, which can be used in some embodiments of the present disclosure;

FIG. 11 is an exemplary diagram for explaining a 2D feature associated with the length of paths and how to extract such 2D feature, which can be used in some embodiments of the present disclosure;

FIG. 12 is an exemplary diagram for explaining a 2D feature associated with a grid region and how to extract such 2D feature, which can be used in some embodiments of the present disclosure;

FIGS. 13 through 15 are exemplary diagrams for explaining a 2D feature associated with the length of overlapping paths and how to extract such 2D feature, which can be used in some embodiments of the present disclosure;

FIG. 16 is an exemplary diagram for explaining a 2D feature associated with the number of branches and how to extract such 2D feature, which can be used in some embodiments of the present disclosure;

FIG. 17 is an exemplary diagram for explaining how to train a deep learning model according to some embodiments of the present disclosure;

FIG. 18 illustrates the form of input data for the deep learning model according to some embodiments of the present disclosure;

FIGS. 19 through 21 illustrate exemplary structures of the deep learning model according to some embodiments of the present disclosure;

FIG. 22 illustrates the form of output data of the deep learning model illustrated in FIG. 21; and

FIG. 23 illustrates an exemplary computing device that can implement the routing system according to some embodiments of the present disclosure.

### DETAILED DESCRIPTION

Hereinafter, example embodiments of the present disclosure will be described with reference to the attached drawings. Advantages and features of the present disclosure and methods of accomplishing the same may be understood more readily by reference to the following detailed description of example embodiments and the accompanying drawings. The present disclosure may, however, be embodied in many different forms and should not be construed as being limited to the embodiments set forth herein. Rather, these embodiments are provided so that this disclosure will be thorough and complete and will fully convey the concept of the disclosure to those skilled in the art, and the present disclosure will only be defined by the appended claims.

In adding reference numerals to the components of each drawing, it should be noted that the same reference numerals are assigned to the same components as much as possible even though they are shown in different drawings. In addition, in describing the present disclosure, when it is determined that the detailed description of the related well-known configuration or function may obscure the gist of the present disclosure, the detailed description thereof will be omitted.

Unless otherwise defined, all terms used in the present specification (including technical and scientific terms) may be used in a sense that may be commonly understood by those skilled in the art. In addition, the terms defined in the commonly used dictionaries are not ideally or excessively interpreted unless they are specifically defined clearly. The terminology used herein is for the purpose of describing particular embodiments only and is not intended to be limiting of the disclosure. In this specification, the singular also includes the plural unless specifically stated otherwise in the phrase.

In addition, in describing the component of this disclosure, terms, such as first, second, A, B, (a), (b), may be used. These terms are only for distinguishing the components from other components, and the nature or order of the components is not limited by the terms. If a component is described as being “connected,” “coupled” or “contacted” to another component, that component may be directly connected to or contacted with that other component, but it should be understood that another component also may be “connected,” “coupled” or “contacted” between each component.

Embodiments of the present disclosure will be described with reference to the attached drawings.

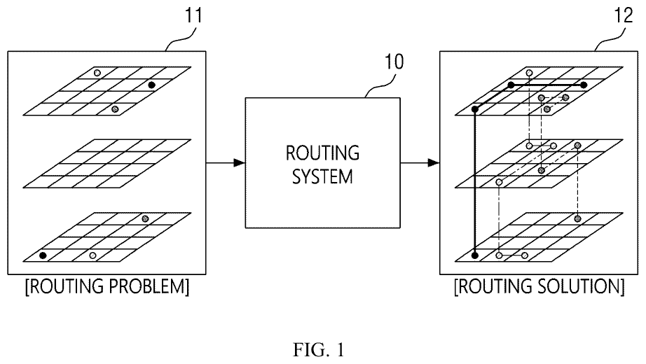

FIG. 1 is an exemplary diagram for explaining the operation of a routing system according to some embodiments of the present disclosure.

Referring to FIG. 1, a routing system 10 is a computing device/system capable of generating a solution 12 (i.e., routing results) to a multilayer structure-based routing problem 11. For example, the routing system 10 may determine the routing order (i.e., the sequence of path creation/derivation) for multiple node groups disposed in a multilayer structure and may execute a routing algorithm based on the determined routing order to generate paths 12 for the multiple node groups.

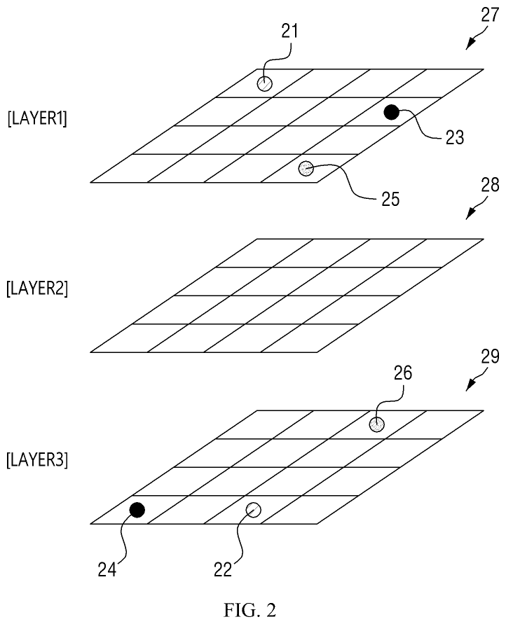

For the convenience of understanding, the routing problem 11 will hereinafter be described with reference to FIG. 2. In FIG. 2 and the subsequent drawings, nodes belonging to the same node group are depicted in the same color (or hatching).

Referring to FIG. 2, the routing problem 11 refers to a problem that generates a path set for multiple node groups disposed in a multilayer structure, i.e., a first node group (21 and 22), a second node group (23 and 24), and a third node group (25 and 26). Here, the path set may refer to a collection of individual paths. For example, the set path may include a first path connecting nodes in the first node group (21 and 22), a second path connecting nodes in the second node group (23 and 24), and a third path connecting nodes in the third node group (25 and 26). The path set may also be referred to as a collection of paths, a group of paths, etc., or simply as paths.

The multilayer structure refers to a three-dimensional (3D) structure composed of a plurality of layers. Examples of the multilayer structures include a building composed of multiple layers, a Printed Circuit Board (PCB), a semiconductor package/chip, etc., but the present disclosure is not limited thereto. FIG. 2 illustrates a multilayer structure composed of three layers, i.e., layers 27 through 29. The multilayer structure may be represented as a multilayer grid map, as illustrated in FIG. 2, but the present disclosure is not limited thereto. However, for convenience, it is assumed that a multilayer structure corresponding to a routing environment can be represented as a multilayer grid map.

Within the multilayer structure, more than one link may be formed between neighboring layers (e.g., between the layers 27 and 28 or between the layers 28 and 29). The links form parts of a path and may represent a connection passage that penetrates between the neighboring layers (e.g., between the layers 27 and 28). For example, if the multilayer structure is a building, the links may be stairs or elevators connecting floors. Alternatively, if the multilayer structure is a PCB or a semiconductor package, the links may be vias formed to connect wirings between layers.

The nodes (e.g., nodes 21 and 23) in the multilayer structure represent elements (or points) that require connections (i.e., the creation of paths). Nodes may be disposed on any layer. Nodes may be disposed within cells of a multi-layer grid map or at the vertices of the cells. Nodes may also be referred to as points, pins, connection targets, connection elements, or vertices.

The multiple node groups (e.g., the first node group (21 and 22)) represent collections (or sets) of nodes that need to be connected. Consequently, the routing problem 11 may be understood as being a problem of creating paths that connect nodes within the same node group. Each node group (e.g., the first node group (21 and 22)) may include a departing (or starting) node, which corresponds to the beginning of a path, a destination (or end) node, which corresponds to the destination of the path, and one or more intermediate nodes, but the present disclosure is not limited thereto.

The multiple node groups (e.g., the first node group (21 and 22)) may be understood as being equivalent to nets in the field of semiconductors. The nodes (e.g., the node 21) may be understood as corresponding to bond fingers in a semiconductor package or solder balls connected to the bond fingers through wiring.

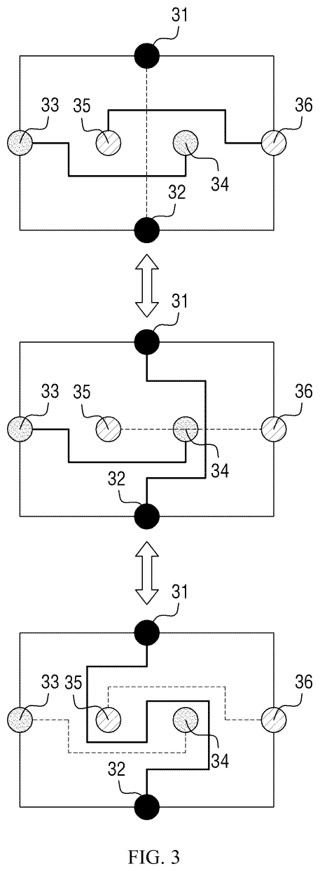

To generate an optimal path set for the routing problem 11, it is necessary to accurately determine the routing order for the multiple node groups (e.g., the first node group (21 and 22)) because routing outcomes may significantly vary depending on the sequence in which the multiple node groups are routed. For example, as illustrated in FIG. 3, the success of routing and the total cost associated with a path set may greatly differ depending on the sequence in which multiple node groups, i.e., three node groups (31 and 32, 33 and 34, and 35 and 36), are routed.

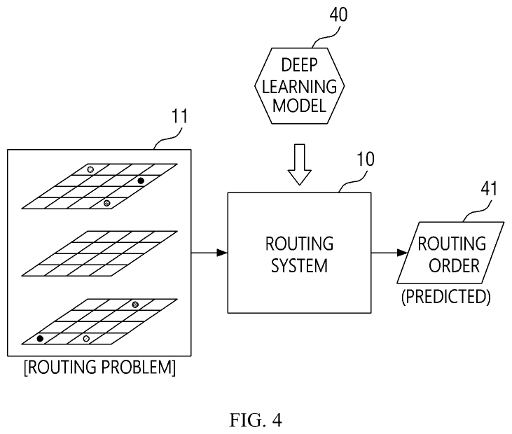

Determining the routing order for the multiple node groups (e.g., the first node group (31 and 32)) is a combinatorial optimization problem and a non-deterministic polynomial (NP)-hard problem that cannot be solved in polynomial time. Therefore, in various embodiments of the present disclosure, a deep learning model (“40” of FIG. 4) may be used to effectively and efficiently solve such problem.

Specifically, as illustrated in FIG. 4, the routing system 10 may train the deep learning model 40 through a routing order prediction task (or a routing cost prediction task), and may predict a routing order 41 for the multiple node groups (e.g., the first node group (21 and 22)) defined in the routing problem 11, using the trained deep learning model 40. Then, the routing system 10 may generate a path set for the multiple node groups (e.g., the first node group (21 and 22)) by executing a routing algorithm based on the predicted routing order 41. In this manner, an optimal (or near-optimal) routing solution 12 to the routing problem 11 can be accurately produced at a reduced computational cost.

Here, creating the path set for the multiple node groups (e.g., the first node group (21 and 22)) may be understood as creating respective paths for the multiple node groups.

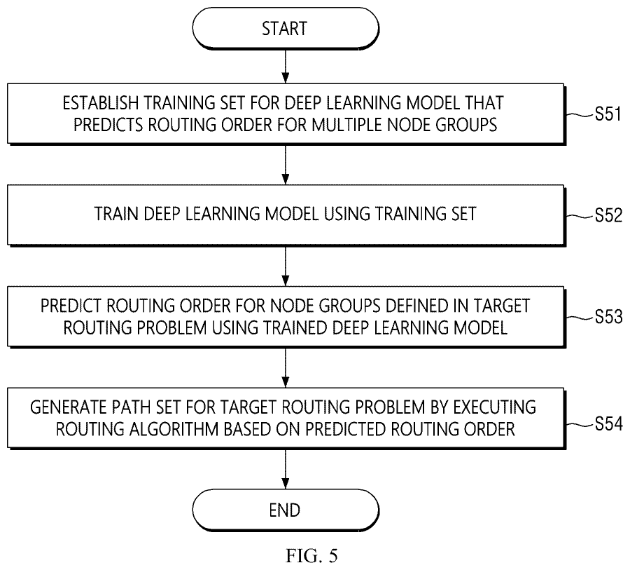

A method by which the routing system 10 trains the deep learning model 40 will be described later with reference to FIG. 5 and the subsequent drawings.

The routing system 10 may be implemented as at least one computing device. For example, all functions of the routing system 10 may be implemented in one computing device, or first and second functions of the routing system 10 may be implemented in first and second computing devices, respectively. Alternatively, a specific function of the routing system 10 may be implemented across multiple computing devices.

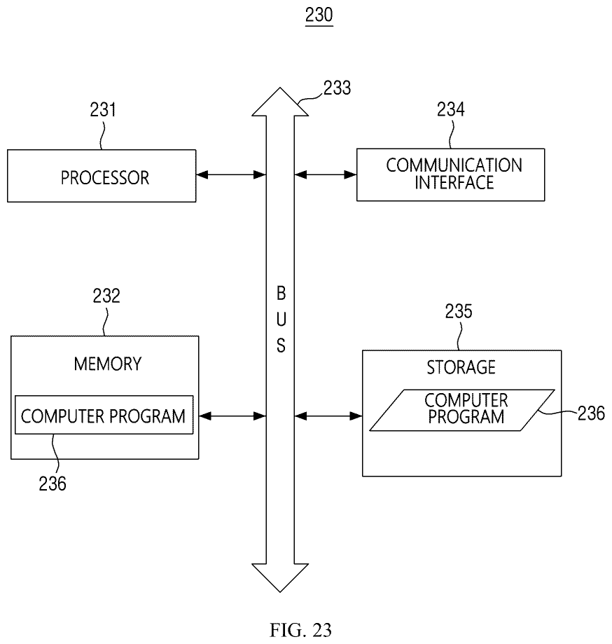

The term “computing device” may encompass any type of device equipped with computing functionalities, and an exemplary computing device will be described later with reference to FIG. 23. As a computing device is an assembly where various components (e.g., memories, processors, etc.) interact, it may sometimes be referred to as a computing system, which may also encompass the concept of an assembly where multiple computing devices interact.

The operation of the routing system 10 has been described so far with reference to FIGS. 1 through 4.

Various methods that can be performed within the routing system 10 will hereinafter be described with reference to FIG. 5 and the subsequent drawings.

For ease of understanding, it is assumed that all steps/operations of the methods that will hereinafter be described are performed by the routing system 10. If the subject of a specific step/operation is omitted, it may be understood that the specific step/operation is performed by the routing system 10. However, in an actual environment, some steps/operations of the methods that will hereinafter be described may be performed by different computing devices. For example, the training of the deep learning model 40 may be conducted on a separate computing device

FIG. 5 is a flowchart illustrating a routing method in a multilayer structure according to some embodiments of the present disclosure. The embodiment of FIG. 5 is merely exemplary for achieving the objectives of the present disclosure, and some steps may be added or omitted as necessary.

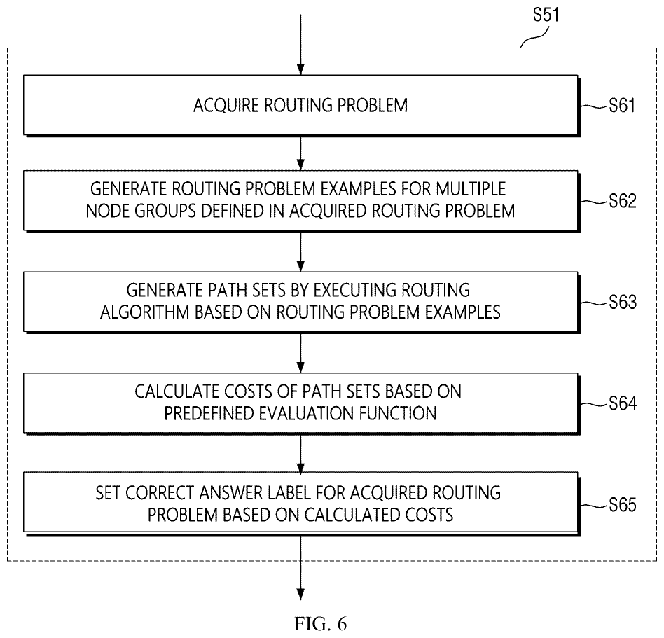

Referring to FIG. 5, the routing method may begin with step S51, which involves constructing a training set for training the deep learning model 40. The details of step S51 are as illustrated in FIG. 6. Step S51 will hereinafter be described with reference to FIG. 6.

Referring to FIG. 6, in step S61, a routing problem (i.e., a routing problem example) may be acquired. For example, the routing system 10 may acquire various routing problems for an effective training of the deep learning model 40. As mentioned earlier, a routing problem may refer to a problem of creating a path set for multiple node groups within a multilayer structure, which may be represented by, for example, a multilayer grid map.

The acquisition of a routing problem may vary from one embodiment to another. For example, the routing system 10 may acquire a routing problem from a known routing problem database (DB). Alternatively, the routing system 10 may generate a second routing problem by modifying an existing first routing problem in various manners (e.g., changing node positions, adding or removing nodes, etc.). Yet alternatively, the routing system 10 may randomly arrange a plurality of nodes on a multilayer grid map and may appropriately group nodes to be connected, thereby generating a third routing problem.

In step S62, routing order examples for the multiple node groups defined in the acquired routing problem may be generated. The routing system 10 may create various routing order examples for the node groups. Here, the term “example” may also be referred to as a sample or a case.

The creation of routing order examples may vary from one embodiment to another.

In some embodiments, routing order examples may be generated using a heuristic algorithm. For example, the routing system 10 may calculate the costs of various routing order examples (i.e., the costs of path sets generated based on the various routing order examples) and may select routing order examples whose costs are below a certain threshold. In this manner, a high-quality routing order example (i.e., a routing order example that can generate a cost-effective path set) can be generated with a low computational cost. The cost of a path set (or the cost corresponding to a routing order example) may also be referred to as a routing cost.

A heuristic evaluation function may be a function that estimates the cost of a path set generated based on a specific routing order. The heuristic evaluation function may be defined based on various factors (or metrics), such as the length of the path set, the occurrence of intersections among paths, etc. For example, the heuristic evaluation function may be defined as shown in Equation 1 below, but the present disclosure is not limited thereto.

$$Score ( {T}_{i} ) = \frac{α}{length ( {T}_{i} )} + \frac{β}{pinNum ( {T}_{i} )} + \frac{γ}{intersection ( {T}_{i} )} \qquad [ Equation 1 ]$$

In Equation 1, Score(Tᵢ) represents a score corresponding to the cost of a path set Tᵢ, with a higher score indicating a lower cost, length(Tᵢ) represents the length of the path set Tᵢ (e.g., the sum of the lengths of individual paths in the path set Tᵢ), pinNum(Tᵢ) represents the number of nodes in the path set Tᵢ, which considers not only actual nodes in the corresponding node group, but also virtual nodes at both ends of each link, and virtual nodes at direction change points in each path, intersection(Tᵢ) indicates the number of intersections in the path set Tᵢ (e.g., where different paths cross each other), and α, β, and γ represent weights for these factors (or metrics).

Alternatively, in some embodiments, routing order examples may be generated using a meta-heuristic algorithm. For example, the routing system 10 may modify existing routing order examples using a genetic algorithm, thereby creating new routing order examples. Even in this example, high-quality routing order examples can be produced with low computational costs. The operating principles of the genetic algorithm are already well known in the field to which the present disclosure pertains, and thus, a detailed description thereof will be omitted.

Alternatively, in some embodiments, routing order examples may be generated by randomly assigning the routing order for each node group.

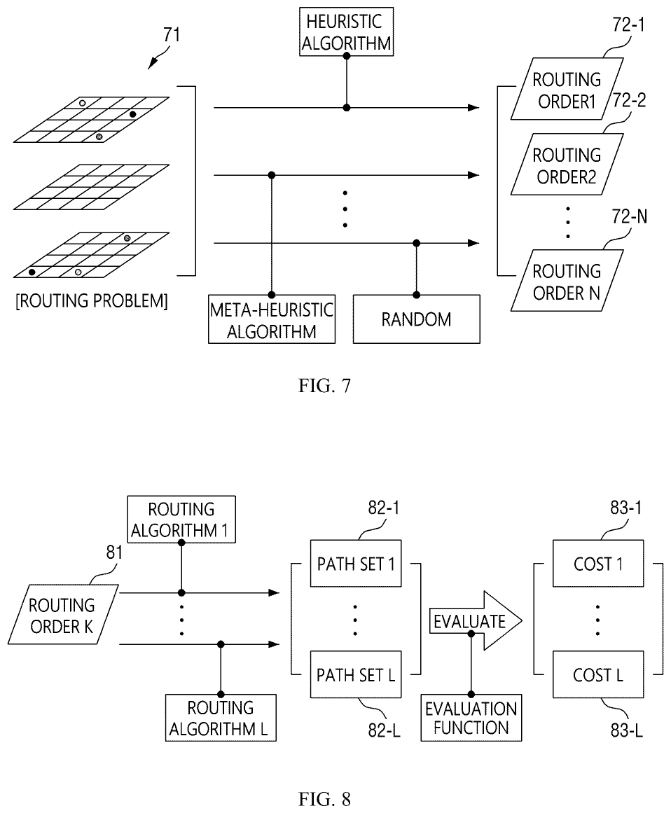

Yet alternatively, in some embodiments, routing order examples may be generated based on various combinations of the aforementioned embodiments. For example, as illustrated in FIG. 7, the routing system 10 may generate routing order examples (e.g., 72-1 and 72-2) multiple node groups defined in a routing problem 71, using a heuristic algorithm and a meta-heuristic algorithm, and may create additional routing order examples (e.g., 72-N) by randomly assigning routing orders. Still alternatively, the routing system 10 may create additional routing order examples by transforming routing order examples generated through the heuristic algorithm, using the meta-heuristic algorithm.

Referring again to FIG. 6, in step S63, path sets for the multiple node groups defined in the acquired routing problem, i.e., solutions for the acquired routing problem, may be generated. For example, the routing system 10 may generate multiple path sets for the acquired routing problem (i.e., path sets for the multiple node groups defined in the acquired routing problem) by executing a predetermined routing algorithm (e.g., a 3D routing algorithm considering a multilayer structure) based on multiple routing order examples. Examples of the routing algorithm include the A* algorithm, Kruskal's algorithm, and the Steiner tree algorithm, but the present disclosure is not limited thereto.

Specifically, as illustrated in FIG. 8, the routing system 10 may generate one or more path sets 82-1 through 82-L by executing a designated routing algorithm based on a routing order example 81. In this case, the routing system 10 may calculate costs 83-1 through 83-L of the path sets 83-1 through 83-L using a predefined evaluation function, and may determine the final cost of the routing order example 81 based on a statistical value (e.g., average, median, mode, etc.) from the calculated costs 83-1 through 83-L. The evaluation function will be described later in further detail.

Referring again to FIG. 6, in step S64, the costs of the generated path sets from step S63 may be calculated based on a predefined evaluation function. For example, the routing system 10 may calculate the cost of each of the generated path sets based on the evaluation function. The routing system 10 may calculate the cost of each path or the cost of each path set.

The evaluation function is a function defined to calculate the cost of a path set (or a path), i.e., a routing cost, in consideration of various factors (or metrics), such as connection success rate, the length of each path set, the length of overlapping paths (e.g., total length, maximum length, etc.), the number of branches, and other design rules. For example, the evaluation function may be defined as shown in Equation 2 below, but the present disclosure is not limited thereto.

$$Score ( D ) = \frac{α}{1 + \sum TOF} + \frac{β}{1 + \sum MOF} + \frac{γ}{\sum length + \sum branch} \qquad [ Equation 2 ]$$

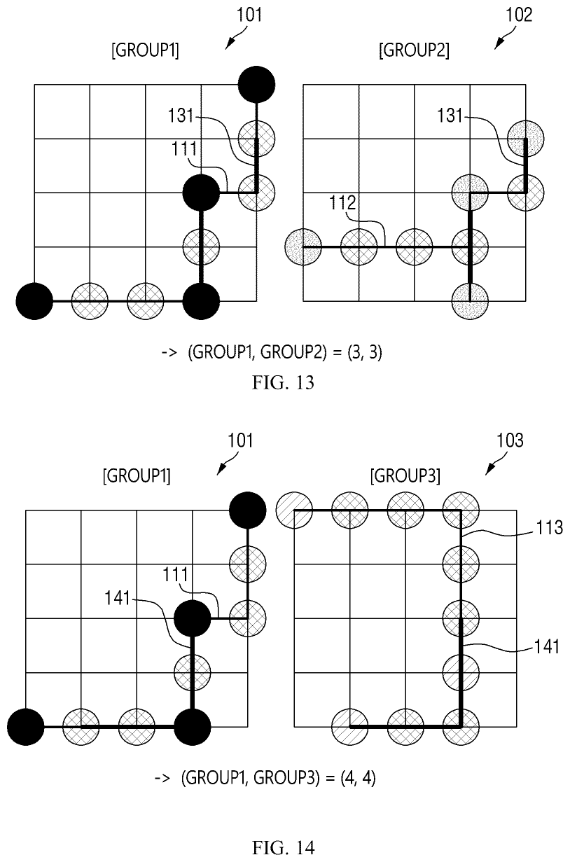

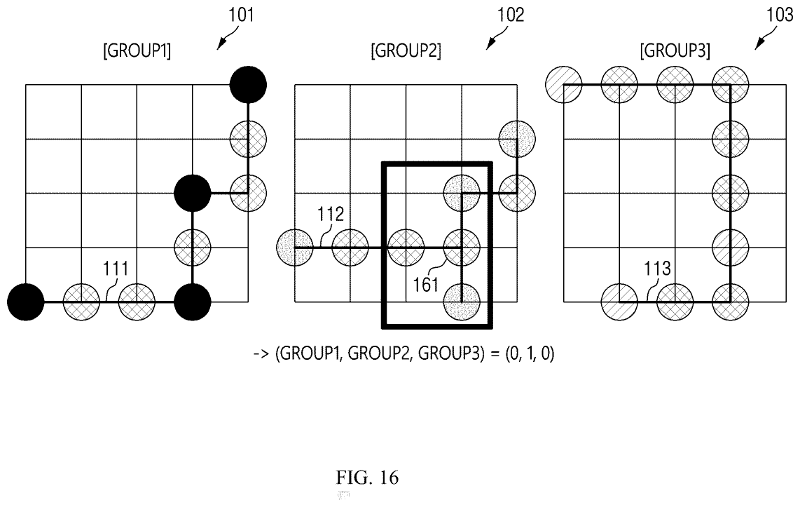

In Equation 2, Score(D) represents a score corresponding to the cost of a path set D, with a higher score indicating a lower cost, the symbol Σ represents summation, TOF (Total OverFlow) represents the length of overlapping paths, i.e., the length of sections of a particular path that overlap with other paths (see FIGS. 13 through 15), MOF (Maximum OverFlow) represents the maximum length of the overlapping paths, “length” represents the length of individual paths within the path set D, “branch” represents the number of branches occurring within each path (see FIG. 16), and α, β, and γ represent weights for these factors (or metrics).

In step S65, a correct answer label for the acquired routing problem may be set based on the calculated costs. The correct answer label may vary depending on the task (e.g., the prediction target) or output of the deep learning model 40.

For example, if the deep learning model 40 is configured to output values representing routing orders for input node groups (i.e., to perform a routing order prediction task), then the routing system 10 may select a routing order example with a lowest cost (or highest score) among multiple routing order examples as the correct answer label for the acquired routing problem.

Conversely, if the deep learning model 40 is configured to receive information on multiple node groups with a particular routing order and output predicted costs for respective path sets (or paths) for the multiple node groups (i.e., to perform a routing cost prediction task), then the routing system 10 may set the cost associated with a particular routing order example as the correct answer label for that particular routing order example. In a case where multiple routing order examples exist for a single routing problem, multiple correct answer labels may be generated.

Steps S61 through S65 may be repeatedly performed for other routing problems, thereby constructing a diverse and comprehensive training set.

In some embodiments, the routing system 10 may extract various features from routing results (e.g., path sets) for use in training the deep learning model 40. These features provide the deep learning model 40 with additional information that can influence the routing results, which can help reduce the task difficulty (i.e., prediction difficulty) for the deep learning model 40 and enhance prediction accuracy. For example, the routing system 10 may extract features as listed in Table 1 below, but the present disclosure is not limited thereto. The routing system 10 may also extract other features such as the spacing between paths, the number of intersections, etc. The routing system 10 may extract features for each node group (or each path) or for each path set. In Table 1, “3D features” refer to features extracted from a multilayer grid map that reflects routing results, whereas “2D features” refer to features extracted from a single-layer grid map.

TABLE 1

| Category | | Example |
|---|---|---|
| Node | Importance | Priority/importance of node |
| Group/Cluster | Level | groups (by design rules) |
| Features | | Priority/importance of node clusters |
| | | (A node cluster (or supergroup) refers to |
| | | a collection of node groups with the |
| | | same purpose/attributes) |
| | Cluster | Name/identifier of node cluster |
| | | Common attributes of node |
| | | groups within node cluster |
| | | (e.g., type, path length, etc.) |
| | | Common design rules applicable to |
| | | node groups within node cluster |
| | | (e.g., maximum path length, etc.) |
| 3D Features | Number of | Number of nodes per node group |
| | Nodes | disposed on multilayer grid map |
| | | Total number of nodes disposed |
| | | on multilayer grip map |
| 2D Features | Number of | Number of nodes per node group |
| | Nodes | disposed on single-layer grid map |
| | | Total number of nodes disposed |
| | | on single-layer grid map |
| | Path Length | Path length per node group |
| | | on single-layer grid map |
| | | Length of path sets on |
| | | single-layer grid map |
| | Grid Region | Horizontal length, vertical |
| | Horizontal | length, and area of grid region |
| | Length/Vertical | for each node group that includes |
| | Length/Area | paths on single-layer grid map |
| | | Horizontal length, vertical length, |
| | | and area of grid region that includes |
| | | path set on single-layer grid map |
| | Length of | Length of overlapping sections |
| | Overlapping | between different paths on |
| | Paths | single-layer grid map |
| | Number of | Number of branches present in paths |
| | Branches | on single-layer grid map |
| | | (number of branches per node group) |
| | | Number of branches present in path |
| | | set on single-layer grid map |

In Table 1, the “Node Group/Cluster Features” may refer to features defined based on design rules, the Importance/Priority may refer to the significance or precedence of routing connections, the “Common attributes” may refer to attributes such as, for example, the common path length that node groups within each node cluster should have in common, or the type of node groups (e.g., whether the node groups are node groups that transmit signals, node groups that transmit power, etc.), and the “Common design rules” may refer to design rules applicable universally to node groups within each node cluster (e.g., maximum path length, maximum number of vias, allowance for overlaps/intersections, etc.).

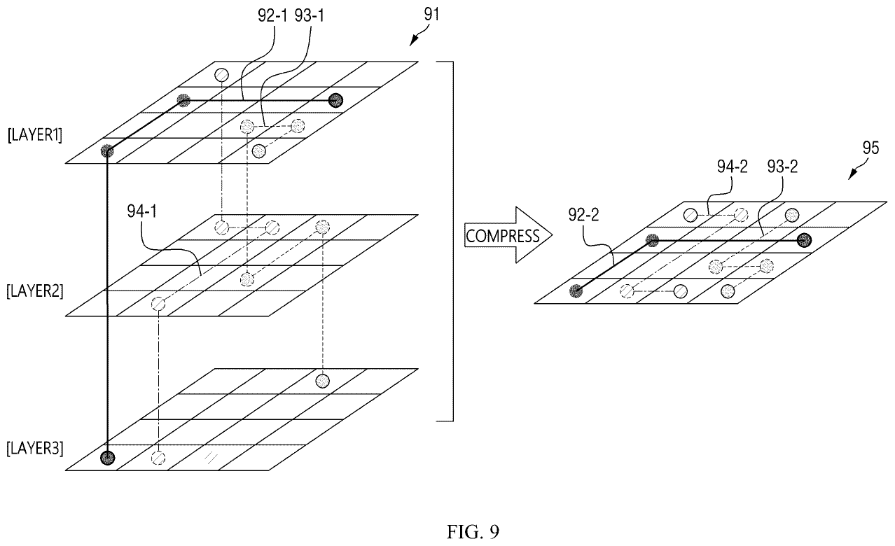

The extraction of 2D features will hereinafter be described with reference to Table 1 and FIGS. 9 through 16.

FIG. 9 illustrates a method of creating a single-layer grid map according to some embodiments of the present disclosure. A multilayer grid map and a single-layer grid map may also be referred to as a 3D grid map and a 2D grid map, respectively. Additionally, paths on a multilayer grid map and paths on a single-layer grid map may also be referred to as 3D paths and 2D paths, respectively.

Referring to FIG. 9, the routing system 10 may create a single-layer grid map 95 by compressing a multilayer grid map 91 to extract 2D features. For example, the routing system 10 may project each layer of the multilayer grid map 91 (i.e., a 2D grid map corresponding to each layer of the multilayer grid map 91) onto a single-layer grid map to create a single-layer grid map 95. As a result, 3D paths 92-1, 93-1, and 94-1 on the multilayer grid map 91 may be transformed into 2D paths 92-2, 93-2, and 94-2, respectively, on the single-layer grid map 95. Nodes projected on the single-layer grid map 95 may include not only actual nodes from different layers but also virtual nodes (e.g., nodes at both ends of links, nodes at direction change points, etc.).

Features may be extracted from the single-layer grid map 95 because 2D features can be extracted with less computational costs even during an inference stage. Specifically, most features of the multilayer grid map 91, for example, the length of 3D paths, cannot be used in the inference stage because they are extracted from complete routing results. Additionally, 2D routing, which generates 2D paths, can be performed quickly and without the constraints of other node groups' design rules, considering only the situations of individual node groups using a deterministic method, rather than an NP-hard algorithm. Therefore, during the inference stage, the routing system 10 can quickly secure 2D features for a target routing problem by arranging the node groups of the target routing problem onto a single-layer grid map and executing a routing algorithm. In short, the routing system 10 can quickly obtain 2D routing results and easily secure 2D features from the 2D routing results. For these reasons, the 2D features extracted from the single-layer grid map 95 may be used in training the deep learning model 40.

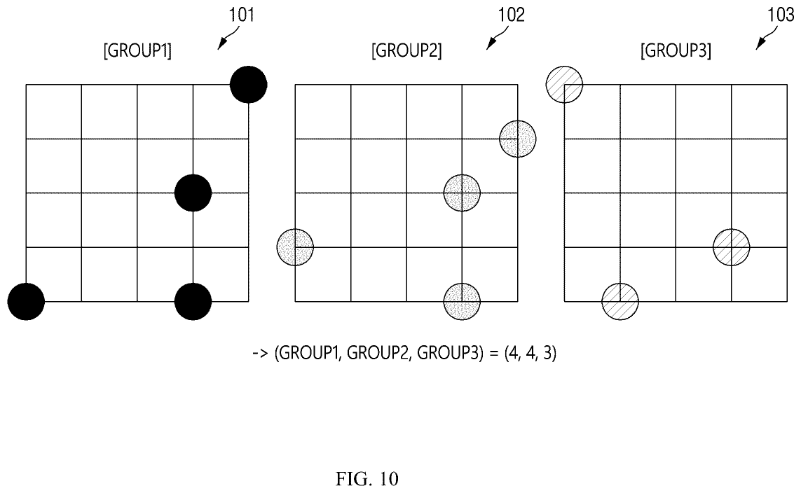

The extraction of the 2D features shown in Table 1 will hereinafter be described with reference to FIGS. 10 through 16. FIGS. 10 through 16 assume the presence of three node groups, i.e., first, second, and third node groups. For clarity, the first, second, and third node groups may also be referred to simply as first, second, and third groups (“Group 1,” “Group 2,” and “Group 3”), respectively, and paths in the first, second, and third groups will hereinafter be referred to as first, second, and third paths, respectively.

FIG. 10 illustrates how to extract a 2D feature associated with the number of nodes. FIG. 10 and the subsequent drawings assume the extraction of a 2D feature from each node group, and illustrate separate single-layer grid maps for different node groups, for convenience.

Referring to FIG. 10, the routing system 10 may count the numbers of nodes located in single-layer grid maps 101 through 103 for the first, second, and third groups, respectively, and may thereby acquire a 2D feature (e.g., (Group 1, Group 2, Group 3)=(4, 4, 3)).

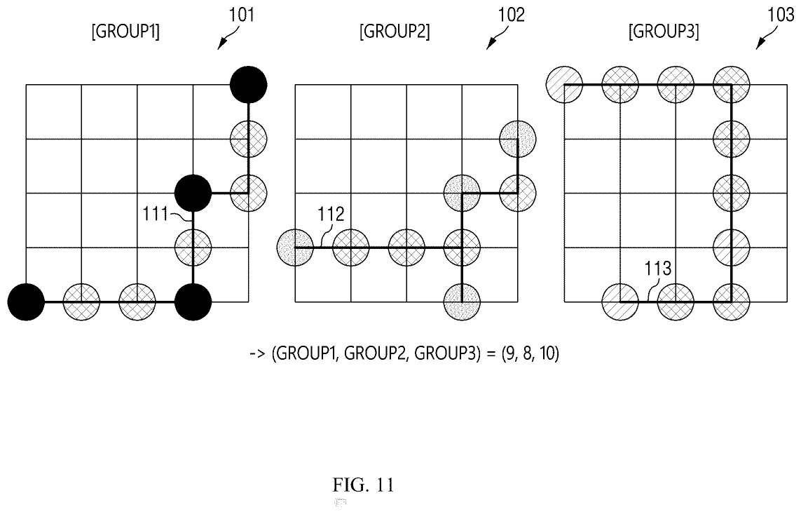

FIG. 11 illustrates how to extract a 2D feature associated with the length of paths.

Referring to FIG. 11, the routing system 10 may calculate the lengths of first, second, and third paths 111, 112, and 113 on the single-layer grid maps 101, 102, and 103, respectively, and may thereby acquire a 2D feature (e.g., (Group 1, Group 2, Group 3)=(9, 8, 10)). In FIG. 11, it is assumed that the length of a path is measured by the number of vertices forming that path, but the present disclosure is not limited thereto.

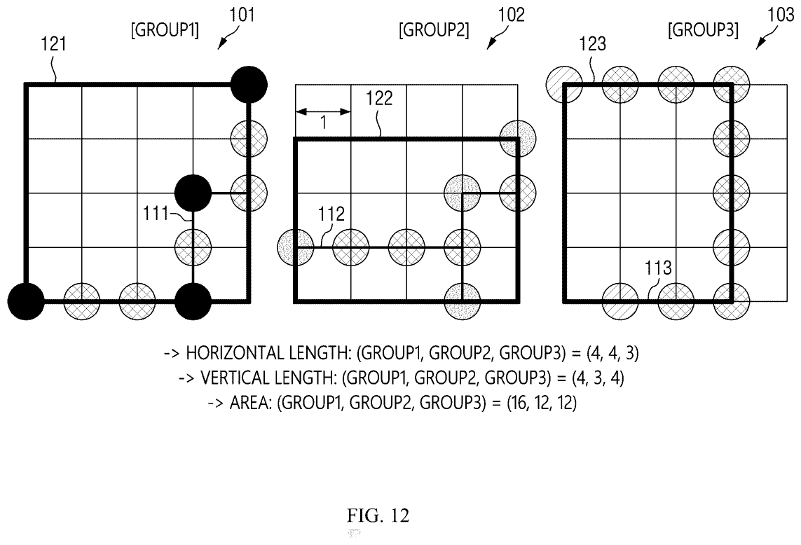

FIG. 12 illustrates how to extract a 2D feature associated with grid regions containing paths.

Referring to FIG. 12, the routing system 10 may calculate the horizontal lengths, vertical lengths, and areas of grid regions 121 through 123 containing the paths 111, 112, and 113, respectively, on the single-layer grid maps 101, 102, and 103, respectively, and may thereby acquire a 2D feature (e.g., Horizontal Length=(4, 4, 3)). In FIG. 12 and the subsequent drawings, it is assumed that the horizontal and vertical lengths of the cells of each grid map are both 1.

FIGS. 13 through 15 illustrate how to extract a 2D feature associated with the length of overlapping paths.

Referring to FIG. 13, the routing system 10 may identify an overlapping section 131 between the first and second paths 111 and 112, on the single-layer grid maps 101 through 103, and may calculate the length of the identified overlapping section 131.

Thereafter, referring to FIG. 14, the routing system 10 may also calculate the length of an overlapping section 141 between the first and third paths 111 and 113, on the single-layer grid maps 101 through 103.

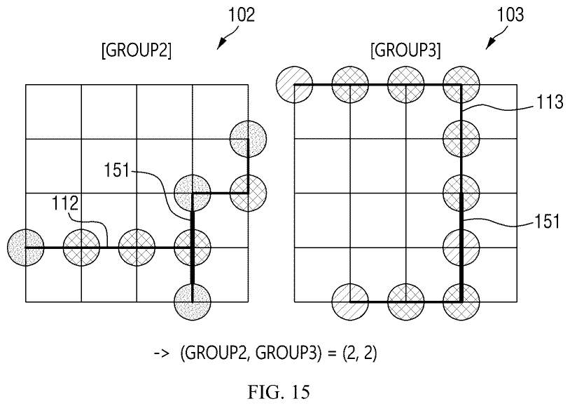

Thereafter, referring to FIG. 15, the routing system 10 may also calculate the length of an overlapping section 151 between the second and third paths 112 and 113.

The routing system 10 may then sum up the results of these calculations to acquire 2D feature (e.g., (3, 3, 0)+(4, 0, 4)+(0, 2, 2)=(7, 5, 6)).

FIG. 16 illustrates how to extract a 2D feature associated with the number of branches.

Referring to FIG. 16, the routing system 10 may count the numbers of branches present in the first, second, and third paths 111, 112, and 113 on the single-layer grid maps 101, 102, and 103, respectively, and may thereby acquire a 2D feature (e.g., (0, 1, 0)).

Once these 2D features are extracted, the routing system 10 may add them to construct a training set. A single routing problem may form one sample in the training set (e.g., when one correct answer label associated with a routing cost is assigned (or set) per routing problem) or multiple samples (e.g., when multiple correct answer labels regarding routing costs are assigned per routing problem). The training set may be configured to include routing problem information (e.g., node group information including position information of a plurality of node groups, multilayer grid map information, etc.), feature information, and correct answer labels, but the present disclosure is not limited thereto.

Referring back to FIG. 5, in step S52, the deep learning model 40 may be trained using the training set. For example, the routing system 10 may iteratively update the weight parameters of the deep learning model 40 by performing a routing order prediction task using the samples in the training set. This enables the deep learning model 40 to accurately predict a routing order suitable for a routing problem (or for a plurality of node groups). Alternatively, the routing system 10 may update the parameters of the deep learning model 40 by performing a routing cost prediction task using the samples in the training set.

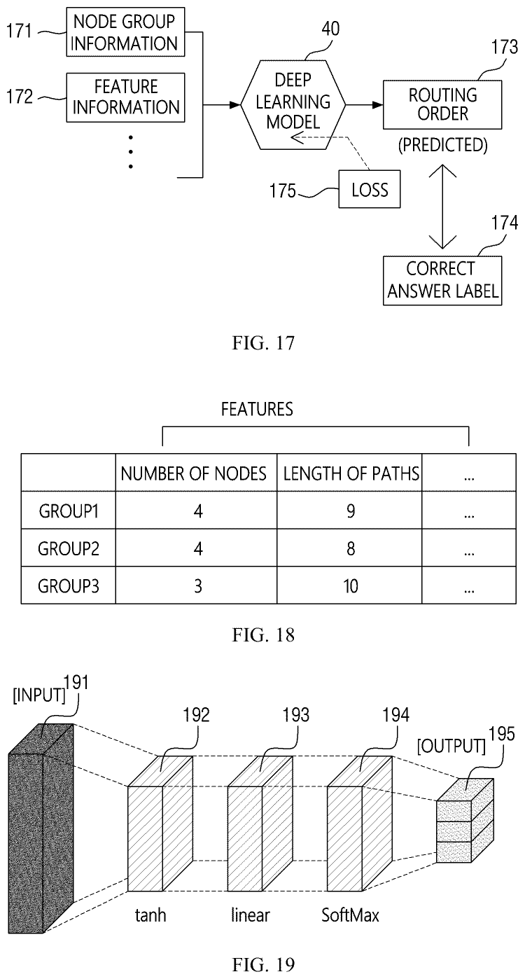

For example, it is assumed that the deep learning model 40 is configured to output values representing routing orders. In this case, referring to FIG. 17, the routing system 10 may predict a routing order 173 by inputting node group information 171 (e.g., position information of multiple node groups) and feature information 172 of a training set into the deep learning model 40. For example, the routing system 10 may configure input data, as illustrated in FIG. 18, using the node group information 171 and the feature information 172 and may then input the input data into the deep learning model 40, but the present disclosure is not limited thereto. Subsequently, the routing system 10 may update the weight parameters of the deep learning model 40 based on loss 175 between a predicted routing order 173 and a correct answer label 174 (e.g., a routing order with a cost below a threshold). The loss 175 may be calculated using a loss function such as Mean Square Error (MSE) or cross-entropy, but the present disclosure is not limited thereto.

In another example, it is assumed that the deep learning model 40 is configured to output a cost corresponding to a routing order, i.e., routing cost (e.g., to output the total cost for a path set or the cost per path). In this example, the routing system 10 may input node group information (e.g., position information of node groups having a particular routing order corresponding to a correct answer label) and feature information of a training sample into the deep learning model 40 to predict a routing cost. Then, the routing system 10 may update the weight parameters of the deep learning model 40 based on the loss (e.g., MSE loss) between a predicted routing cost and the correct answer label (e.g., the cost calculated in step S64 corresponding to the particular routing order).

The deep learning model 40 may be configured and implemented based on various neural networks. For example, the deep learning model 40 may be configured and implemented based on an Artificial Neural Network (ANN), Deep Neural Network (DNN), Convolutional Neural Network (CNN), or Graph Neural Network (GNN). Additionally, the format of input data may vary depending on the type of neural network the deep learning model 40 is based on. For example, if the deep learning model 40 is implemented based on a CNN, the node group information 171 may be input as images (e.g., layer-by-layer images) of a multilayer grid map, and the feature information 172 may also be input as images (e.g., images of a single-layer grid map, as depicted in FIGS. 10 through 16). As another example, if the deep learning model 40 is implemented based on a GNN, both the node group information 171 and the feature information 172 may be input as graph data (e.g., an adjacency matrix representing paths).

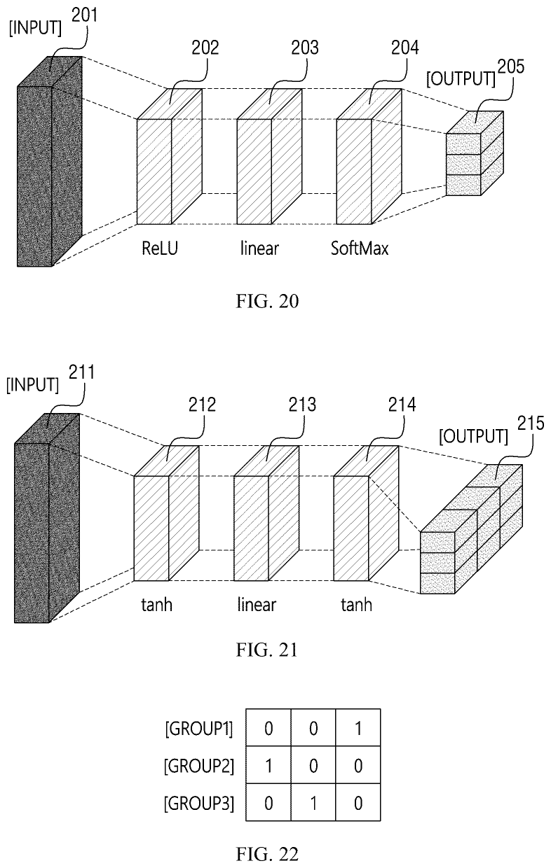

FIGS. 19 through 21 illustrate exemplary structures of the deep learning model 40, assuming that the deep learning model 40 is implemented based on an ANN or DNN. Specifically, FIGS. 19 and 20 assume that output data 195 and 205 consist of scalar values representing the routing order for each node group, and FIG. 21 assumes that output data 215 consists of vector values (e.g., one-hot vectors exemplified in FIG. 22). When the deep learning model 40 outputs data as depicted in FIG. 21 or 22, a cross-entropy loss function may be used to calculate losses, but the present disclosure is not limited thereto.

The structure and operating principles of layers 192 through 194, 202 through 204, or 212 through 214 depicted in FIGS. 19 through 21 are well known in the field to which the present disclosure pertains, and thus, detailed descriptions thereof will be omitted.

Referring back to FIG. 5, in step S53, the routing order for the multiple node groups defined in the target routing problem may be predicted using the trained deep learning model 40. Here, the target routing problem refers to a routing problem to be solved, i.e., a routing problem at the inference stage.

For example, the routing system 10 may compress a multilayer grid map with multiple node groups disposed thereon, thereby creating a single-layer grid map, and may extract features, such as those set forth in Table 1, from the single-layer grid map. A 3D feature associated with the number of nodes can be directly calculated from the target routing problem. The routing system 10 may then derive paths (i.e., 2D paths) for node groups on the single-layer grid map by executing a simple 2D routing algorithm. The routing system 10 may extract various 2D features (e.g., the lengths of paths, the lengths of overlapping paths, etc.) based on the derived paths. The routing algorithm used to derive the 2D paths may be, for example, the Minimum Spanning Tree (MST) algorithm, the Minimum Rectilinear Steiner Tree (MRST) algorithm, etc., but the present disclosure is not limited thereto. These algorithms have low complexity and do not require extensive computational resources, thus allowing the routing system 10 to quickly and easily extract various 2D features. In other words, since design rules in a multilayer structure typically do not allow overlaps or intersections among node groups, actual routing may necessitate the use of complex algorithms. However, extracting 2D features, which involves finding simple connection paths while ignoring such overlaps/intersections, can be performed with low computational costs.

Thereafter, the routing system 10 may predict a routing order that will be applied to the multiple node groups, by inputting information on the multiple node groups and information on the extracted features into the trained deep learning model 40.

For example, if the deep learning model 40 is configured to output values representing routing orders, a predicted routing order for the multiple node groups may be determined based on the output data of the trained deep learning model 40.

As another example, if the deep learning model 40 is configured to output routing costs, the routing system 10 may predict routing costs through the deep learning model 40 by changing routing orders. Moreover, the routing system 10 may determine a routing order with a predicted routing cost below a threshold as a routing order to be applied to the multiple node groups.

In step S54, a path set for the target routing problem may be generated by executing a routing algorithm for the multiple node groups within the multilayer structure based on the predicted routing order. For example, the routing system 10 may generate paths (i.e., 3D paths) for the respective node groups on a multilayer grid map based on the predicted routing order. This routing algorithm, unlike a 2D routing algorithm, must adhere to original design rules (e.g., no overlaps/intersections allowed) and are generally complex and require substantial computational resources.

The routing method in a multilayer structure according to some embodiments of the present disclosure have been described so far with reference to FIGS. 5 through 22. According to the described method, the routing order for multiple node groups can be predicted through the deep learning model 40, and a path set for the multiple node groups can be generated by executing a routing algorithm based on the predicted routing order. In this case, the computational cost of creating the path set can be significantly reduced (as there is no need to repeatedly execute the routing algorithm by changing routing orders), and a suitable (i.e., optimal or near-optimal) path set can be accurately generated for the multiple node groups.

Furthermore, utilizing heuristic or meta-heuristic algorithms can create high-quality routing order examples with low computational costs, thus improving the performance (i.e., prediction accuracy) of the deep learning model 40 that predicts routing orders.

Additionally, by modifying existing routing problems or randomly arranging nodes, diverse routing problems can be generated, enriching the training set and further enhancing the performance of the deep learning model 40.

Also, using routing order examples with routing costs below a threshold as correct answer labels can also boost the performance of the deep learning model 40.

Lastly, employing various 2D features associated with 3D routing results as inputs for the deep learning model 40 can lower the task difficulty of the deep learning model 40 and enhance the precision accuracy of the deep learning model 40.

An exemplary computing device that can implement the routing system 10 will hereinafter be described with reference to FIG. 23.

FIG. 23 is an exemplary hardware configuration view of a computing device 230.

Referring to FIG. 23, the computing device 230 may include at least one processor 231, a bus 233, a communication interface 234, a memory 232, which loads a computer program 236 executed by the processor 231, and a storage 235, which stores the computer program 236. FIG. 23 illustrates only components related to the embodiments of the present disclosure, and it is obvious to one of ordinary skill in the art to which the present disclosure pertains that other general-purpose components than those illustrated in FIG. 23 may also be included in computing device 230. That is, the computing device 230 may further include various components other than those depicted in FIG. 23. In some embodiments, the computing device 230 may be configured without some of the components illustrated in FIG. 23. Each of the components of the computing device 230 will hereinafter be described.

The processor 231 may control the overall operations of the components of the computing device 230. The processor 231 may be configured to include at least one of a Central Processing Unit (CPU), a Micro Processor Unit (MPU), a Micro Controller Unit (MCU), a Graphics Processing Unit (GPU), and any other form of processor well-known in the field of the present disclosure. Moreover, the processor 231 may perform computations for at least one application or program to execute operations/methods according to some embodiments of the present disclosure. The computing device 230 may be equipped with one or more processors 231.

The memory 232 may store various data, commands, and/or information. The memory 232 may load the computer program 236 from the storage 235 to execute the operations/methods according to some embodiments of the present disclosure. The memory 232 may be implemented as a volatile memory such as a Random-Access Memory (RAM), but the present disclosure is not limited thereto.

The bus 233 may provide communication functions between the components of the computing device 230. The bus 233 may be implemented in various forms, such as an address bus, a data bus, or a control bus.

The communication interface 234 may support wired or wireless Internet communications for the computing device 230. Moreover, the communication interface 234 may support various other communication methods than the Internet communication method. For this, the communication interface 234 may be configured to include a well-known communication module in the field of the present disclosure.

The storage 235 can non-transiently store one or more computer programs 236. The storage 235 may be configured to include a non-volatile memory such as a Read-Only Memory (ROM), an Erasable Programmable ROM (EPROM), an Electrically Erasable Programmable ROM (EEPROM), a flash memory, a hard disk, a removable disk, or any form of computer-readable recording medium well known in the technical field of the present disclosure.

The computer program 236 may include one or more instructions that, when loaded into the memory 232, cause the processor 231 to perform the operations/methods according to some embodiments of the present disclosure. That is, by executing the instructions loaded into the memory 232, the processor 231 may perform the operations/methods according to some embodiments of the present disclosure.

For example, the computer program 236 may include instructions for the operations of: acquiring a routing problem; generating a routing order example for multiple node groups; generating a path set for the multiple node groups based on the routing order example; establishing a training set by calculating the cost of the generated path set based on a predefined evaluation function; and training the deep learning model 40 to predict a routing order using the training set. In this case, the routing system 10 may be implemented via the computing device 230.

Meanwhile, in some embodiments, the computing device 230 of FIG. 23 may represent a virtual machine implemented based on cloud technology. For example, the computing device 230 may be a virtual machine operating on one or more physical servers included in a server farm. In this case, at least some of the processor 231, the memory 232, and the storage 235 may be implemented as virtual hardware, and the communication interface 234 may be implemented as a virtualized networking element, such as a virtual switch.

The computing device 230 that can implement the routing system 10 has been described so far with reference to FIG. 23.

Embodiments of the present disclosure have been described above with reference to FIGS. 1 through 23, but it should be noted that the effects of the present disclosure are not limited to those described above, and other effects of the present disclosure should be apparent from the following description.

The technical features of the present disclosure described so far may be embodied as computer readable codes on a computer readable medium. The computer program recorded on the computer readable medium may be transmitted to other computing device via a network such as internet and installed in the other computing device, thereby being used in the other computing device.

Although operations are shown in a specific order in the drawings, it should not be understood that desired results may be obtained when the operations must be performed in the specific order or sequential order or when all of the operations must be performed. In certain situations, multitasking and parallel processing may be advantageous. In concluding the detailed description, those skilled in the art will appreciate that many variations and modifications may be made to the example embodiments without substantially departing from the principles of the present disclosure. Therefore, the disclosed example embodiments of the disclosure are used in a generic and descriptive sense only and not for purposes of limitation.

The protection scope of the present invention should be interpreted by the following claims, and all technical ideas within the equivalent range should be interpreted as being included in the scope of the technical ideas defined by the present disclosure.

What is claimed is:

1. A routing method in a multilayer structure, performed by at least one computing device, comprising:
acquiring a routing problem, wherein the routing problem is a problem of generating a path set that includes respective paths for multiple node groups arranged in a multilayer structure;
generating a routing order example for the multiple node groups;
generating a path set for the multiple node groups by executing a routing algorithm based on the routing order example;
establishing a training set by obtaining a cost of the generated path set based on a predefined evaluation function; and
training a deep learning model to predict a routing order using the training set.

2. The routing method of claim 1, wherein
the acquired routing problem includes a plurality of routing problems, and
the plurality of routing problems include a first routing problem, a second routing problem generated by modifying the first routing problem, and a third routing problem generated by randomly disposing a plurality of nodes in the multilayer structure.

3. The routing method of claim 1, wherein
the generating the routing order example, comprises generating the routing order example using a predefined heuristic evaluation function, and
the predefined heuristic evaluation function is a function that estimates a cost of a path set generated based on a specific routing order.

4. The routing method of claim 1, wherein the generating the routing order example, comprises generating the routing order example by modifying an existing routing order example using a genetic algorithm.

5. The routing method of claim 1, wherein the generating the path set, comprises generating a plurality of path sets by executing a plurality of different routing algorithms.

6. The routing method of claim 1, wherein
the routing problem is defined based on a multilayer grid map,
the establishing the training set, comprises: creating a single-layer grid map by compressing the multilayer grid map; and extracting at least one feature that constitutes an input for the deep learning model from the single-layer grid map.

7. The routing method of claim 6, wherein the at least one feature includes a number of nodes in a specific node group on the single-layer grid map.

8. The routing method of claim 6, wherein the extracting the at least one feature, comprises: deriving a path that connects nodes belonging to a specific node group on the single-layer grid map; and extracting a feature for the specific node group based on the derived path.

9. The routing method of claim 8, wherein the extracting the feature for the specific node group, comprises extracting a length of the derived path as the feature for the specific node group.

10. The routing method of claim 8, wherein the extracting the feature for the specific node group, comprises extracting at least one of a horizontal length, vertical length, and area of a grid region containing the derived path on the single-layer grid map as the feature for the specific node group.

11. The routing method of claim 8, wherein the extracting the feature for the specific node group, comprises extracting a number of branches present on the derived path as the feature for the specific node group.

12. The routing method of claim 6, wherein the extracting the at least one feature, comprises: deriving a first path that connects nodes belonging to a first node group among the multiple node groups on the single-layer grid map; deriving a second path that connects nodes belonging to a second node group among the multiple node groups on the single-layer grid map;
and extracting a feature for the first node group or the second node group by measuring a length of an overlapping section between the first path and the second path.

13. The routing method of claim 6, wherein
the multiple node groups are multiple first node groups, and
the routing method further comprises: acquiring a target multilayer grid map where multiple second node groups are disposed; extracting a feature for the multiple second node groups from a single-layer grid map obtained by compressing the target multilayer grid map; and predicting a routing order to be applied to the multiple second node groups by inputting information on the multiple second node groups and the feature for the multiple second node groups into the trained deep learning model.

14. The routing method of claim 1, wherein
the establishing the training set, comprises establishing the training set by adding features of a node cluster that includes at least some of the multiple node groups,
the node cluster refers to a collection of node groups with the same purpose or the same attributes, and
the features of the node cluster include at least one of importance, common attributes, and common design rules.

15. The routing method of claim 1, wherein
the deep learning model is configured to output values representing routing orders for input node groups,
among the generated routing order examples, a routing order example with an obtained cost below a threshold is set as a correct answer label for the multiple node groups, and
the training the deep learning model, comprises: predicting a routing order for the multiple node groups through the deep learning model; and updating weight parameters of the deep learning model based on a loss between the predicted routing order and the correct answer label.

16. The routing method of claim 1, wherein
the deep learning model is configured to output a cost of a path set for node groups having a specific routing order,
the obtained cost is set as a correct answer label for the multiple node groups, and
the training the deep learning model, comprises: predicting a cost corresponding to a routing order associated with a correct answer label through the deep learning model; and updating weight parameters of the deep learning model based on a loss between the predicted cost and the correct answer label.

17. The routing method of claim 1, wherein
the multiple node groups are multiple first node groups, and
the routing method further comprises: acquiring a target multilayer grid map where multiple second node groups are disposed; extracting a feature for the multiple second node groups from a single-layer grid map obtained by compressing the target multilayer grid map; and predicting a routing order to be applied to the multiple second node groups by inputting information on the multiple second node groups and the feature for the multiple second node groups into the trained deep learning model.

18. A routing system comprising:
at least one processor; and
a memory configured to store a computer program executable by the at least one processor,
wherein the computer program includes instructions for operations of:
acquiring a routing problem, wherein the routing problem is a problem of generating a path set that includes respective paths for multiple node groups arranged in a multilayer structure;
generating a routing order example for the multiple node groups;
generating a path set for the multiple node groups by executing a routing algorithm based on the routing order example;
establishing a training set by obtaining a cost of the generated path set based on a predefined evaluation function; and
training a deep learning model to predict a routing order using the training set.

19. A non-transitory computer-readable medium storing a computer program that is executable by at least one processor to execute:
acquiring a routing problem, wherein the routing problem is a problem of generating a path set that includes respective paths for multiple node groups arranged in a multilayer structure;
generating a routing order example for the multiple node groups;
generating a path set for the multiple node groups by executing a routing algorithm based on the routing order example;
establishing a training set by obtaining a cost of the generated path set based on a predefined evaluation function; and
training a deep learning model to predict a routing order using the training set.
